(19) United States
(12) Patent Application Publication
(10) Pub. No.: US 2004/0232982 A1
(43) Pub. Date: Nov. 25, 2004

(54) RF front-end module for wireless communication devices

(76) Inventors: Ikuroh Ichitsubo, (US); Guan-Wu Wang, (US); Weiping Wang, (US)

Correspondence Address: TRAN & ASSOCIATES, 6768 MEADOW VISTA CT., SAN JOSE, CA, 95135, US

(21) Appl. No.: 10/843,409

(22) Filed: May 10, 2004

Related U.S. Application Data
(63) Continuation-in-part of application No. 10/385,058, filed on Mar. 9, 2003, now Pat. No. 6,774,718.
(60) Provisional application No. 60/397,261, filed on Jul. 19, 2002.

(51) Int. Cl. H03G 3/20

(52) U.S. Cl. 330/129

(57) ABSTRACT

Systems and methods are disclosed for a device with an active substrate comprising substantially transistors or diodes formed thereon, the active substrate having at least a power amplifier formed thereon; a passive substrate comprising substantially inductors, capacitors or resistors formed thereon; a plurality of bonding pads positioned on the active and passive substrates; and bonding wires connected to the bonding pads.

This application is a continuation in part of application Ser. No. 10/385,058 filed on Mar. 9, 2003, titled “Power Amplifier Module for Wireless Communication Devices”, which in turn claims priority to Provisional Application Ser. No. 60/397,261, filed on Jul. 19, 2002, titled “Power Amplifier Modules for Wireless LAN Applications”, the contents of which are incorporated by reference. The application is also related to the commonly assigned U.S. patent application Ser. No. 10/041,863, filed on Oct. 22, 2001, titled “Multilayer RF Amplifier Module”, by Wang, et al., and the commonly assigned and concurrently filed U.S. patent application “Accurate Power Sensing Circuit for Power Amplifiers” by Ichitsubo et al. The disclosures of these related applications are incorporated herein by reference.

### BACKGROUND

The present invention relates to radio frequency (RF) power amplifiers (PA) module. Portable devices such as laptop personal computers (PC), Personal Digital Assistant (PDA) and cellular phones with wireless communication capability are being developed in ever decreasing size for convenience of use. Correspondingly, the electrical components thereof must also decrease in size while still providing effective radio transmission performance. However, the substantially high transmission power associated with RF communication increases the difficulty of miniaturization of the transmission components.

A major component of the wireless communication device is the radio frequency PA. The PA is conventionally in the form of a semiconductor integrated circuit (IC) chip or die in which signal amplification is effected with substantial power. The amplifier chip is interconnected in a circuit with certain off-chip components such as inductors, capacitors, resistors, and transmission lines used for controlling operation of the amplifier chip and providing impedance matching of the input and output RF signals. The amplifier chip and associated components are typically assembled, on a printed circuit board (PCB) in which the components are interconnected by layers printed metal circuits and layers of dielectric substrates.

One important consideration for wireless devices is to properly control the quality and power level of the amplified RF signals to be transmitted. In particular for high data rate wireless communications, the amplification of RF signals is required to be linear over a wide signal power range and over a given frequency range. Preferably the amplification is reduced or increased according to input RF signal, transmittance range and data rate so that power consumption can be optimized.

Among important considerations in wireless devices are the grounding and RF signal isolation. A power amplifier typically has high current flowing through the circuit. A non-zero impedance in the circuit can easily induce a voltage, potentially injecting unwanted noise into the RF system. Poor circuit board grounding can thus cause unintended feedback and oscillations. The ground current paths and the current handling capability of components have to be considered carefully. Since RF circuits operate at high power and high signal frequencies, electromagnetic radiation created can interfere with other components of the wireless communication device, or with other electronic devices.

Another significant consideration in the miniaturization of RF amplifier circuits is the required impedance matching for the input and output RF signals of the amplifier. Input and output impedance matching circuits typically include capacitors, resistors, and inductors in associated transmission lines or micro strips for the RF signals into and out of the amplifier chip. However, these impedance matching circuits may require specifically tailored off-chip components located remotely from the amplifier IC chip. Accordingly, the application circuitry must include many electrical input and output terminals or bonding Pins to which the corresponding portions of the off-chip impedance matching circuits are separately joined. This increases the difficulty of assembly and required size of the associated components, and affects the overall manufacturability of the portable devices.

### SUMMARY

In one aspect, systems and methods are disclosed for a device with an active substrate comprising substantially transistors or diodes formed thereon, the active substrate having at least a power amplifier formed thereon; a passive substrate comprising substantially inductors, capacitors or resistors formed thereon; a plurality of bonding pads positioned on the active and passive substrates; and bonding wires connected to the bonding pads.

Implementations of the device may include one or more of the following. The module can be made of one or more Active substrates for active and certain supporting passive components. The module can include one or more substantially passive substrates for passive components only. The substrates are interconnected with bonding wires. The substrates can be mounted on a metal lead-frame, or can be encapsulated in molded plastics. The active substrate contains primarily for transistors, which could be either Silicon Bipolar, CMOS, RFCMOS, BICOMS, SiGe, GaAs HBT, HEMT, etc. They are typically made from more expensive wafers with the semiconductor layer structure, junctions, and dopings. The passive substrate is for circuits network of R, L, C which do not need active device structure. A few conductive metal layers can be used on the passive substrate for inductor (L) and interconnection. An insulating layer with suitable dielectric properties such as Nitride or Oxide can be used as the dielectric layer for capacitor (C). The passive substrate can include a layer such as TaN and NiCr for resistor (R). Passive components can still be on the die of the Active IC, but the circuit of passive components such as transmission lines, impedance matching network, filters, balun, and diplexers are located in the inexpensive dies of passive substrate. Typically, a diplexer consists of a set of two band pass filters or a set of high pass and low pass filter.

Advantages of the module can include one or more of the following. A wireless radio frequency (RF) module can be fabricated to minimize device count and/or printed circuit board real estate. The active substrates contain high-value circuits such as power amplifiers, LNAs, and switches, among others. The passive substrates are formed on semi-insulating GaAs or insulator wafer without the active transistor structure layer, which lower the cost of wafer and processing time. Passive components are made with precision semiconductor process with high quality control of component values. Comparing with PCB, the higher dielectric constant of GaAs result in smaller size for same RF circuit. The metal lead frame provides better heat dissipation for power devices. RF Modules can be made with metal lead frame, thus eliminating PCB/LTCC substrate and SMD steps for cost reduction. The metal lead frame also allows higher temperature in subsequent manufacturing steps.

Additional features and advantages of the invention will be set forth in the description, which follows, and in part will be obvious from the description, or may be learned by the practice of the invention. The features and advantages of the invention may be realized and obtained by means of the instruments and combinations particularly pointed out in the appended claims. These and other features of the present invention will become apparent from the following description and appended claims, or may be learned by the practice of the invention as set forth hereinafter.

### BRIEF DESCRIPTION OF THE DRAWINGS

In order that the manner in which the above recited and other advantages and features of the invention are obtained, a more particular description of the invention briefly described above will be rendered by reference to specific embodiments thereof, which are illustrated, in the appended drawings. Understanding that these drawings depict only typical embodiments of the invention and are not therefore to be considered to be limiting of its scope, the invention will be described and explained with additional specificity and detail through the use of the accompanying drawings in which:

The accompanying drawings, which are incorporated in and form a part of this specification, illustrate embodiments of the invention and, together with the description, serve to explain the principles of the invention:

FIG. 1 is a system diagram of one embodiment of a power amplifier module for wireless communications.

FIG. 2 is the electrical schematics for the application of the power amplifier module shown in FIG. 1.

FIG. 3 illustrates the use of the power amplifier module for wireless communications.

FIG. 4 shows a diagram of a bottom-side footprint of the power amplifier module and a printed-circuit-board layout of a wireless communication device, on which the power amplifier module is mounted.

FIG. 5 is a system diagram of a module having active and passive IC substrates on a die pad.

FIGS. 6A-6D show various electrical schematics for various wireless module implementations with single-ended or double-ended power amplifiers and low noise amplifiers.

FIG. 7 illustrates an exemplary module pin-out.

FIG. 8 shows a cross-sectional view of another embodiment of a power amplifier.

FIG. 9 shows an RF module with a plurality of active substrates and a plurality of passive substrates.

FIGS. 10A-10D illustrate various exemplary connections between the switch and RF input/output connections.

### DESCRIPTION OF INVENTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

The PA module provides a unitary or common component which may be conveniently assembled in a RF transmission device, with correspondingly simplified assembly, compact 3D size, and enhanced RF amplification performance. In accordance with the present invention, the term “module” refers to such a unitary device for wireless communications, comprising integrated power amplifiers and other circuitry and auxiliary electronic components.

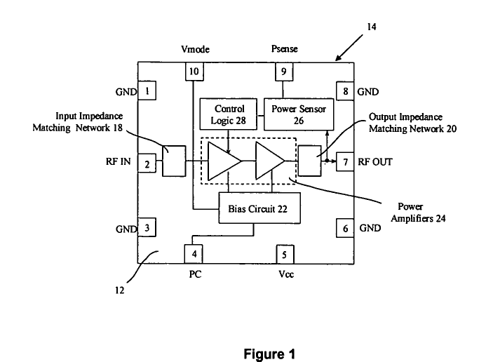

FIG. 1 shows a system diagram of the radio frequency power amplifier (PA) module 14 for wireless communications in accordance to an embodiment of the present invention. The PA module is built on a module substrate 12, which can be a multiplayer printed circuit board (PCB), lead frame, lower-temperature co-fired ceramics (LTCC), or other suitable electronic materials. The substrate includes metal pins adapted to receive connecting terminals of integrated circuits including the Power Amplifiers 24, the Bias Circuit 22, the Power Sensor 26, and optionally Control Logic 28. The Power Amplifiers 24, the Power Sensor 26, the Bias Circuit 22, can be fabricated in an integrated circuit on a semiconductor chip. The Power Amplifiers 24 can be of one or multiple stages. In the particular example shown in FIG. 1, two sequentially connected stages of power transistors are employed. The power amplifier IC has an electrically conductive metal layer to be bonded to the top metal layer of the module. The power amplifier IC 24 can also include, in accordance with another feature of the present invention, input impedance matching circuit 18 and output impedance matching circuit 20. The input and output impedance matching networks are preferably based on the 50-ohm standard of the RF industry. Details of impedance matching circuits are described in the above referenced and commonly assigned U.S. patent application Ser. No. 10/041,863, filed on Oct. 22, 2001, titled “Multilayer RF Amplifier Module”, by Wang, et al.

The PA module 14 amplifies radio frequency signals using: a) a radio frequency power amplifier including one or more semiconductor transistors, adapted to receive an input radio frequency signal and a processed power-sensing control signal, and to output an amplified radio frequency signal; b) a power-sensing circuit adapted to receive the amplified radio frequency signal and to output the power-sensing control signal, and c) a control logic that receives and processes the power-sensing control signal, and outputs a processed power-sensing control signal in response to a quality or a magnitude of the amplified radio frequency signal.

The PA module 14 is a linear amplifier which provides good linearity and low harmnonics over a wide frequency range covering from several megahertz (MHZ) to tens of gigahertz (GHZ) by the feedback control based on the qualities and power level of the amplified radio frequency signal. Specifically, high order inter-modulation distortions are suppressed. The RF amplifier module is suitable to applications in various wireless data and voice communications standards and protocols, including Global System for Mobile Communications (GSM), General Packet Radio Service (GPRS), Code Division Multiple Access (CDMA), Wideband CDMA, IEEE 802.11 Wireless Local Area Network (WLAN) standard and others. The PA module in accordance to the present invention especially provides reliable amplification to the WLAN applications.

In another aspect, a number of electronic components and circuits are integrated within the RF amplifier module, including impedance matching circuits for input and output RF signals. The RF amplifier module is compact and has smaller foot print compared to prior art implementations. The integrated RF amplifier module can be conveniently designed and assembled in a RF transmission device.

Efficient grounding, shielding and thermal conduction is provided in the RF amplifier module. The power amplifier circuit is fabricated on a semiconductor chip having an electrically conductive base. The RF power amplifier module includes a multi-layer three-dimensional substrate having a bottom metal layer adapted to bond with the printed circuit board (PCB) of a wireless communication device. The substrate has one or more upper layers adapted to receive the amplifier chip and other off-chip components. The bottom layer includes grounding metal Pins that are located at the center and at each corner, which is registered and adapted to bond with the circuit pattern on PCB of the wireless communication device. The metal Pins are connected to the upper layers through the multilayer three-dimensional substrate by a plurality of metal via holes

Another feature of the PA module of FIG. 1 is that the output signal from the power sensing circuit can be used to optimally control the bias current and operation characteristics of the power amplifiers. As a result, the PA module provides highly linear output power at reduced current consumption. Yet another feature is that the RF amplifier design enables manufacturing consistency since the input and output matching circuits are included in the module. Common problems related to the manufacturing tolerance of the matching circuit components are therefore eliminated. The RF amplifier design is adapted to high frequency circuitry by utilizing semiconductor materials such as Gallium Arsenide Heterojunction Bipolar Transistors (GaAs HBT).

The Bias Circuit 22 is used to bias individual stage with suitable current so the amplifiers can operate with minimal signal distortion. The Bias Circuit receives input from the power control signal from the PC port (Pin 4) and can be selected to operate at different settings of idle current using the Vmode port (Pin 10). In accordance with the present invention, the mode control signal and the power-control signal may be dependent at least partially on the power-sensing signal output from the Power Sensor circuit 26.

The PA module includes a Power Sensor circuit 26 that senses the level of the output power. Details of the power sensor circuit are disclosed in the above referenced and commonly assigned U.S. patent application “Accurate Power Sensing Circuit for Power Amplifiers” by Ichitsubo et al., the disclosures of which related application are incorporated herein by reference.

A power amplifier with good linearity generally must maintain a constant amplification factor, known as “Gain”, which is defined as the ratio of the output signal power level to the input signal power level. However, at high output power level, the power amplifier can be driven close to saturation and a constant gain becomes difficult to maintain. As a result, the quality of digital communication, commonly measured by Error Vector Magnitude (EVM), Bit Error Rate (BER), or Packet Error Rate (PER), degrades at high output power level.

The Power Sensor 26 receives the amplified radio frequency signal from Power Amplifiers 24 and to output a power-sensing control signal. The Control Logic 28 receives and processes the power-sensing control signal, and outputs a processed power-sensing control signal to control Power Amplifiers 24. The processed power-sensing control signal is a function of a quality or a magnitude of the amplified radio frequency signal. For example, the Control Logic 28 improves the linearity performance of power amplifier using the Power Sensor 26 feedback internally. By adjusting the bias of the amplifier depending on the actual output power measured by the Power Sensor 26, it reduces the tendency of saturation and maintains a more constant gain. Thus the linearity of the amplification over a wide range of power is improved. Yet another method of improving the quality of digital communication is to use an external controller to adjust the input RF signal based the known relationship of digital communication quality to output power level.

The PA module 14 shown in FIG. 1 can be used in a wide range wireless communication devices such as cellular phone, mobile computers, and handheld wireless digital devices. The PA module has a miniature size of a few millimeters.

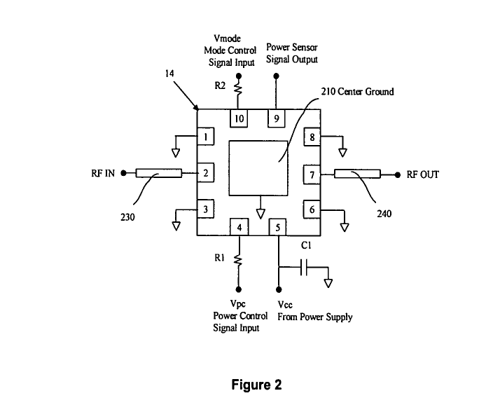

FIG. 2 is the electrical schematics illustrating the application of the PA module 14, as shown in FIG. 1, to wireless communications in accordance to the present invention. The PA module has a plurality of metal Pins, namely, Pin 1 through 10 and the Center Ground 210. Pin 1, 3, 6 and 8 are adapted to be connected to the electric ground. Pin 2 (RF IN port) is connected through a 50-ohm transmission line 230 to an RF input signal to be supplied to the Power Amplifiers 24. The output of the power amplifier chip 24 is at Pin 7 (RF OUT port), also connected by a 50-ohm transmission line 240 to the antenna stage, possibly with a filter and transmit/receive switch in between. Pin 4 (PC port) receives a power control signal, while Pin 5 (Vcc port) receives DC power supply. Pin 9 (Psense port) provides a power sensing signal output, while Pin 10 (Vmode port) optimally receives a mode control signal. A series resistor R₂ can be used to set the DC voltage to Vmode advantageously depending on the requirement of linear power output or the characteristics varying RF signal.

Typically, the power supply comes from a regulated voltage source to the Vcc port. The PA can be switched ON/OFF by presenting a high and low signal at the PC port. The voltage of high signal the PC port may be optimally adjusted with an external resistor R1. When it is switched to the OFF state, the bias to the power amplifier is shut off and the current consumption is reduced to very small.

In one embodiment, the input impedance matching network 18, the output impedance matching network 20, the power amplifiers 24, the bias circuit 22 and the power sensor 26 are integrated on an integrated circuit (IC). The IC includes top terminals or bonding Pins which provide various input and output connections to the internal components of the chip. The top terminals are electrically joined to one or more of the plates in the module substrate 12. In the preferred embodiment, the chip includes Gallium Arsenide Heterojunction Bipolar Transistors (GaAs HBT). However, other semiconductor materials may also be used.

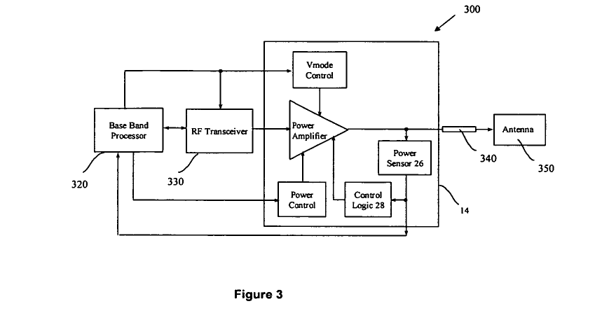

FIG. 3 illustrates an exemplary use of the radio frequency PA module for digital wireless communications in accordance to the present invention. The wireless communication device 300 can be a PDA, a WLAN adaptor, or a cellular phone. The wireless communication device 300 includes a base band processor core 320, RF transceivers 330, PA module 14, and a 50-ohm impedance transmission line or micro strip 340 connected to antenna 350.

A base band chip generates digitally modulated signals. The frequency is up-converted by a RF transceiver to a RF frequency band suitable for transmitting. The RF signal is amplified by the PA module 14 for transmitting by the antenna. The PA module can be turned ON/OFF by the power control signal. The Vmode control (Pin 10) is used to control and internal settings of the bias circuits by the base band processor 320 which has the knowledge of the digital signal modulation type and the linear output requirement. For example, when the device is transmitting high power, the Vmode control pin set the power amplifier operating in high current to minimize output distortion. When the device needs to transmit low power, the Vmode control pin 10 sets the power amplifier with low current to conserve battery life.

The Power Sensor 26 measures the output RF power, which can be advantageously used externally to the PA module. For example, the output of power sensor can be used by the baseband processor 320 to set the transmitting power level for the wireless device by varying the RF input signal to PA module.

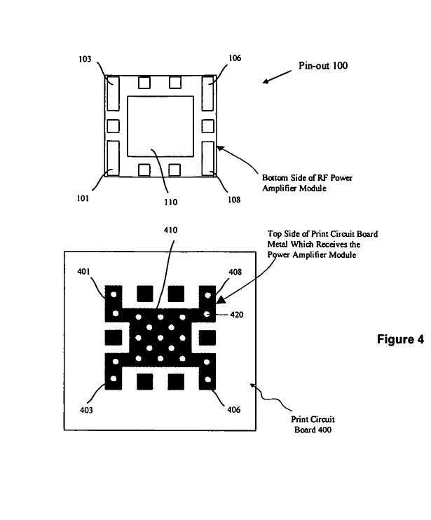

FIG. 4 is a diagram of the pin-out and the footprint of the PA module in accordance with the present invention. The pin-out 100 shows the bottom side of the PA module that includes a multitude of metal electrodes and an insulating substrate. The physical metal pads 101, 103, 106, 108 in FIG. 4 correspond to grounding Pins 1, 3, 6, 8 of the circuit diagram in FIG. 2. The center ground 110 in FIG. 4 corresponds to 210 in FIG. 2.

The center ground 110 serves as major path for dissipating heat generated by the amplifiers. To keep the power amplifier run without excessive temperature, it is important to minimize the heat transfer resistance of the power amplifier to external space on printed circuit. It is also desirable to have minimal electrical resistance for the current flowing between the center ground 110 to the ground of the circuit board of the wireless device.

In the typical application for a wireless communication device, the PA module 14 is electrically mounted to a printed circuit board 400 in the wireless communication device. The circuit board includes a grounding circuit design at the location where the PA module is mounted. The grounding circuit design consists of a metal land 410 and four connecting metal lands 401,403,406, and 408 adjacent to the four corners of 410. When the PA module is mounted to the printed circuit board 400, pins 110, 101, 103, 106 and 108 on the bottom surface of the PA module are mated and connected to 410, 401, 403, 406 and 408, respectively.

The metal circuit 410, 401, 403, 406 and 408 are further connected to a ground plane layer of the circuit board, typically below the RF signal layer, by “via holes” 420. The metal structure together with the via holes illustrated in FIGS. 4 enables effective current flowing from the bottom conductive layer of the amplifier IC chip to the central metal land 410, out to the metal land 401,403,406,408, and continuing down to the ground plane layer by the “via holes” 420.

The grounding structure also provides efficient heat dissipation from the amplifier IC chip in a similar fashion. The design described above is used advantageously to enhance heat transfer capability so the heat can be dissipated horizontally from the center as well as vertically by metal circuit 410, 401, 403, 406, 408 and via holes 420. Both the horizontal and the vertical means of metal circuits together provide a good 3-dimensional topology for heat dissipation path.

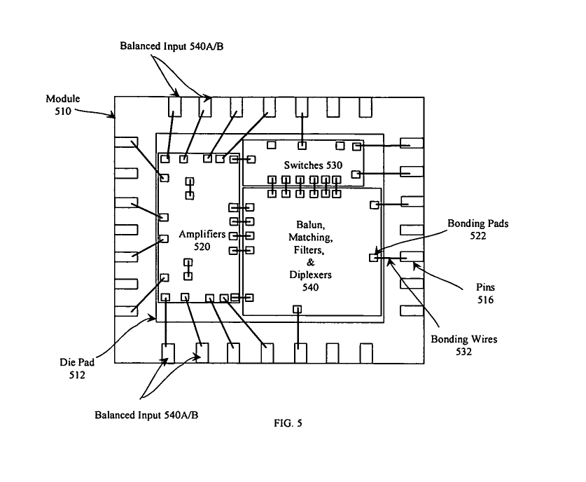

FIG. 5 shows an exemplary module 510 having one or more semiconductor devices. The module 510 can be any suitable communications circuit. The module 510 of FIG. 5 is manufactured to deliver excellent RF or digital performance and reliability at a competitive cost. This is achieved by separating the circuit into one or more active substrates that are electrically connected to one or more passive substrates, all of which are positioned on a lead-frame for subsequent soldering onto a communications printed circuit board.

As illustrated in FIG. 5, the semiconductor module 510 includes a die pad 512 of generally rectangular configuration. The die pad 512 has a surface carrying a plurality of bond pins 516 positioned proximally around the die perimeter. The bond pins 516 make contact with and provide an external contact for internal circuitry (not shown) contained within the semiconductor IC, as is known in the art.

As indicated, the bonding pads 522 are typically formed on the surface of the semiconductor IC substrates and thus extend a distance into the IC substrates through a passivation layer to make electrical contact with the internal circuitry. The pins 516 are preferably formed from a conductive material such as a metal, metal alloy, or any other suitable material known in the art to which a wire bond can be attached. The pins 516 may be silk-screened, printed, sprayed through a patterned mesh, electrochemically deposited, or electroplated, electrolessly plated or otherwise attached to the die surface.

A first active IC substrate 520, a second active IC substrate 530 and a first passive IC substrate 540 are mounted on the die pad 512. In one embodiment, the active IC substrate 520 can include power amplifiers and low noise amplifiers, while the second active IC substrate 530 can include switches thereon. The pins 516 for the active IC substrate 520 can receive single-ended inputs or balanced inputs (differential inputs). The first passive IC substrate 540 includes passive components such as capacitors, inductors or resistors that form filters and diplexers, among others. Each IC substrate 520, 530 or 540 contains a number of bonding pads 522 that are electrically connected (wire-bonded) to other bonding pads 522 on the substrates 520, 530 or 540 or to bonding pins 516 on the die perimeter. Moreover, each IC substrate 520, 530 and 540 may have intra-substrate pads that allow wire-bonding to be done within a substrate.

The first and second active substrates 520 and 530 can be combined into one active substrate, or alternatively, can be split into a number of active substrates. Further, passive devices can be used in the active substrates 520 and 530. However, due to cost and performance reasons, it is preferred that the active substrates 520 and 530 contain mainly active devices such as diodes and transistors that form the PAs and the LNAs. Similarly, due to cost reasons, the passive IC substrate 540 contains mostly passive devices such as capacitors, inductors and resistors even though on occasions, the passive IC substrate 540 can contain a few diodes and transistors that do not need the precision and performance of devices fabricated on the active substrates 520 and 530. In one embodiment, the substrates can be fabricated using Gallium Arsenide and in particular the active substrates can be processed to form Heterojunction Bipolar Transistors (GaAs HBT) thereon. Other semiconductor materials may also be used.

The substrates 520, 530 and 540 may be preformed, and each adhesively attached to the die surface with an adhesive such as an epoxy or other similar material known in the art.

The IC substrates 520, 530 and 540 in the module 510 can be mounted to a conventional lead frame as is known in the art. Alternatively, the lead frame can include a plurality of lead fingers extending outwardly from proximate the perimeter of the module 510 and a die paddle which supports the IC substrates relative to the lead fingers. The lead fingers form leads for a packaged semiconductor device after transfer-molded polymer encapsulation of the module 510 and lead frame as is known in the art.

Wire bonds 532 can then be formed: between bond pad and lead-frame finger; between adjacent or proximate bond pads; between bond pad and intra-chip pad; or between pad and lead finger. The termination points of wire bonds 532 can be of ball, wedge, or other configuration as is known in the art, and formed with a conventional wire bonding machine. Accordingly, a large number of I/O alternative configurations can be achieved for any semiconductor device, depending on the number and layout of the pads and configuration of wire bonds.

In another embodiment, the active substrate 520 is gallium arsenide heterojunction bipolar transistor (HBT) and the active substrate 530 is pseudomorphic high-electron-mobility transistor (PHEMT) substrates.

Materials commonly used in HBT include the aluminum gallium arsenide/gallium arsenide (AlGaAs/GaAs) and indium gallium phosphide/gallium arsenide (InGaP/GaAs) systems because of the wide range of lattice matched compositions. It is also known to use a system where indium gallium arsenide phosphide (InGaAsP) is grown on indium phosphide (InP). The HBT may be formed using MOVCD (Metal Organic Chemical Vapor Deposition) or MBE (Molecular Beam Epitaxy), both are materials science technologies used for growing compound semiconductor-based epitaxial wafers and devices. Also encompassed are InAlAs/InGaAs heterojunction bipolar transistors in which the InP emitter layer is replaced with InAlAs or InAlGaAs. Double heterojunction devices in which the InGaAs collector material is completely or partially replaced with a wider bandgap material like InP, InGaAsP, InAlAs or InAlGaAs are also contemplated. Different base material such as GaAsSb is also contemplated.

Active HBT structures can be etched. In one embodiment, the AlGaAs/GaAs wafer is cleaned and the following fabrication operations are processed:

Emitter Metal Evaporation

Emiter Etching

Cap Layer (InGaAs) Chemical Etching

GaAs/AlGaAs Selective Etching Using RIE

AlGaAs Layer Chemical Etching

Base Metal Evaporation

Base & Collector Mesa Chemical Etching

Collector Metal Evaporation

RTP(Rapid Thermal Process)

Device Isolation Process

Pad Metal Evaporation

Air-Bridge Process

Wafer Lapping

Backside Process Including Via-hole Formation

In one embodiment, the active IC substrate is a field effect transistor (FET), that preferably is a pseudomorphic high-electron-mobility transistor (PHEMT). The fabrication of gallium arsenide structures for active devices may begin by applying an organic photoresist layer on the upper surface of a gallium arsenide substrate and patterning it in an appropriate manner to form, for example, FET active layer mask. The next step is to ion implant impurities through the photoresist mask where there are windows or openings to form a doped region extending from the surface of the gallium arsenide substrate to a predetermined depth. The photoresist layer is subsequently removed and a capping layer is deposited over the gallium arsenide substrate. The material of a capping layer may, for example, be silicon nitride, silicon oxide, phosphorus-doped silicon oxide or aluminum nitride. The purpose of the capping layer is to reduce the outgassing of arsenic from the gallium arsenide substrate when the ion implanted region is annealed. The ion implanted region is annealed by raising the gallium arsenide substrate to a high temperature such as 800° C. to permit recrystallization of the gallium arsenide damaged by the ion implantation. During recrystallization, substitution of the ion implanted ions into the crystal lattices of the gallium arsenide material occurs. After the ion implanted region is annealed, a step also called activation, the capping layer is removed and further processing continues. This includes the formation of ohmic contacts defining drain and source and deposition of material suitable to form the gate of a field effect transistor. The protective capping layer is applied subsequent to the step of ion implantation. After the step of annealing, the capping layer is removed by selective chemical etching. The fabrication of the active structures such as transistors and diodes on the active substrates therefore involve many steps.

Generally speaking, the active IC substrates 520 and 530, either using HBT or PHEMT structure, use many processing steps. In contrast, the passive IC substrate 540 involves relatively simple geometries that define the RLC properties of the respective component being defined. Hence, the fabrication of the passive structures such as resistors, inductors and capacitors on the passive IC substrate 540 involve fewer steps than those for the active substrates 520 and 530. Hence, the active substrates 520 and 530 are more expensive than the passive substrates 540 to fabricate. Thus, it is expected that the yield for the passive substrates is higher than the yield for the active substrates. By separating the manufacturing of passive substrates from the active substrates, over-all yield is improved, thus reducing cost. Moreover, because the passive components are formed using semiconductor manufacturing techniques on gallium arsenide substrates, the electrical property of each passive component can be tightly controlled, thus having an advantage in overall product quality.

Due to the high dielectric constant of GaAs substrates, considerable wavelength reduction occurs at microwave frequencies and the interconnection metals forms waveguide structures on either the active substrates or the passive substrates. Four basic modes of propagation known to who are skilled to the arts, including microstrips, coplanar strips, coplanar waveguides and slot lines can be advantageously adopted for microwave propagation on planar substrates.

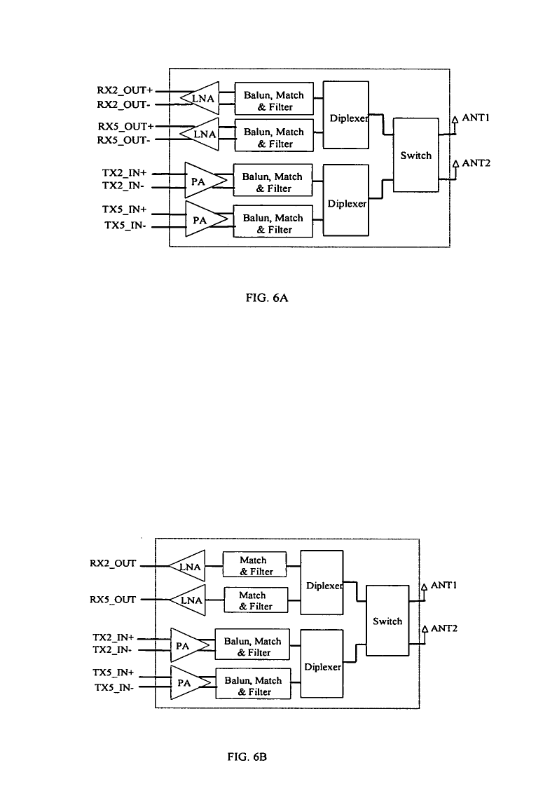

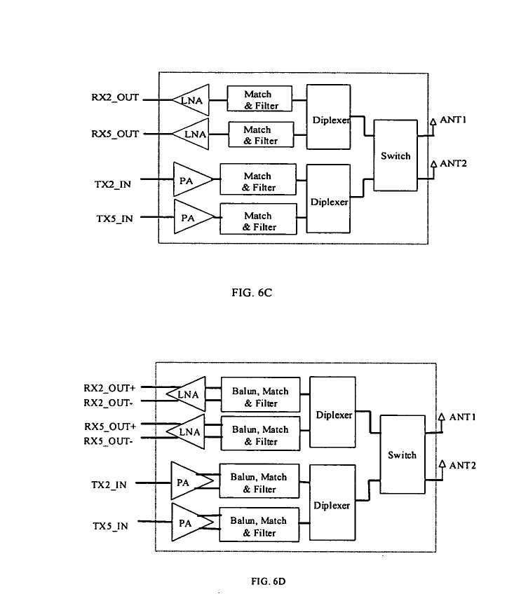

FIGS. 6A-6D show various electrical schematics for various wireless module implementations with single-ended or double-ended power amplifiers. Turning first to FIG. 6C, an exemplary circuit that is partitionable into circuits on an active and a passive substrate is shown with single-ended power amplifiers. In this embodiment is a dual band front-end module (FEM) for communications circuitry such as high performance 802.11 a/b/g wireless LAN circuits. The module can be a unitary device for wireless communications, and can include integrated power amplifiers (PAs), low noise amplifiers (LNAs), switches and other circuitry and auxiliary electronic components, for example. In one embodiment, the module integrates dual band power amplifiers, dual band low noise amplifiers, switch, diplexer, impedance matching networks, bias control, and power sensors to simplify design and production of end products. Bias control and compensation circuitry ensures stable performance over wide operating temperature range.

The circuit of FIG. 6C includes a plurality of filters whose outputs are fed to impedance matching circuits (not shown). The filters and matching circuits are substantially passive circuits, so the filter and match circuits can be placed on the passive IC substrate 540 of FIG. 5. For transmission, the outputs of the matching circuits/networks are provided to power amplifiers PA.

In the embodiment of FIG. 6C, the amplifiers receive single-ended inputs (such as 50 ohm inputs) and the outputs from the LNAs are also single-ended outputs. In other embodiments shown in FIGS. 6A-6B, the power amplifiers receive balanced inputs or differential inputs TX2_IN− and TX2_IN+ as well as TX5_IN+ and TX5_IN−, for example. In one version, the balanced inputs have impedances of 100 ohms. The balanced structure provides increased common-mode rejection, which attenuates common-mode noise and further increases SNR. In FIG. 6B, the outputs from the LNA are single-ended, while in FIG. 6A, the LNA outputs are double-ended. FIG. 6D shows yet another embodiment where the input to each power amplifier PA is single-ended (TX2_IN and TX5_IN), while the LNA outputs are differential (RX2_OUT+ and RX2_OUT−; RX5_OUT+ and RX5_OUT−). In FIGS. 6A, 6B, and 6D, the power amplifier output is provided to a substantially passive circuit such as balun, match and filter circuits. The outputs of each balun, match and filter circuit is presented to a diplexer whose output in turn is presented to a switch to be connected to either antenna ANTI or antenna ANT2. The received RF signal is passed through a second diplexer, whose outputs drive passive circuits that include balun, match and filter circuits. The outputs of the balun, match and filter circuits are presented to low noise amplifiers LNAs to generate received signal outputs.

A balun can be used to convert single-ended input to a differential or double-ended input and vice versa. The balun can be connected to either the input or the output of the power amplifier. The balun is preferably formed on the passive substrate and can be wire-bonded to its respective power amplifier on the active substrate. Additionally, the balun can also be formed on the active substrate for proximity and/or performance reasons.

Correspondingly, for the reception path, the output of low noise amplifiers LNA are provided to the match circuits, filters and baluns. Since the PA and LNA circuits are primarily active, these circuits belong on the active IC substrate 520. The inputs to the LNA and the output from the PA are provided to additional sets of match circuits, filters and diplexer, which are again formed on the passive IC substrate 540 since match circuits, filters and diplexer uses primarily RLC components. The outputs of the diplexers are provided to a switch which in turn is connected to antennas. Since the switch uses transistors, it belongs on an active substrate. In the embodiment of FIG. 5, the switch is fabricated on a separate active IC substrate 530 which is preferable for switching performance and the amplifiers is fabricated on an active IC substrate 520 which is preferable for amplifying performance.

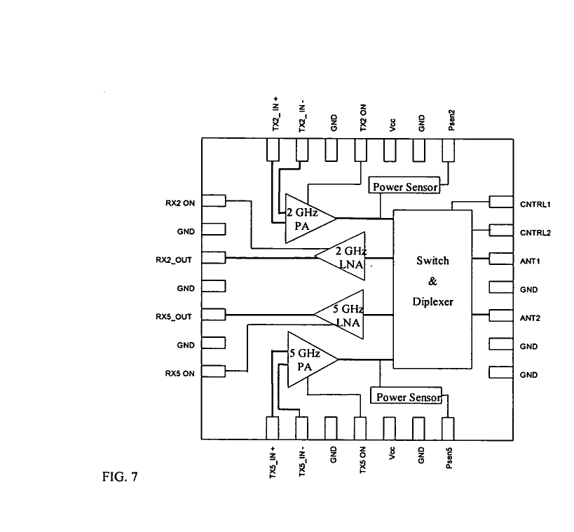

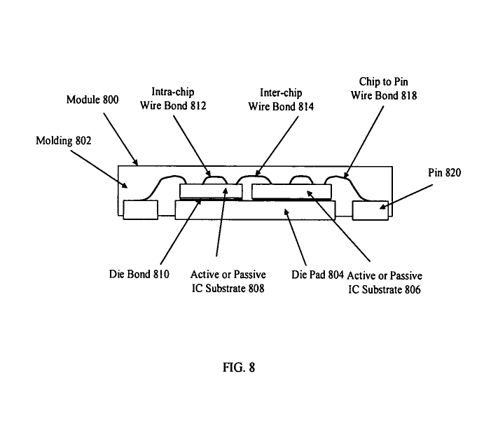

FIG. 7 illustrates an exemplary pin-out diagram of an exemplary IC for the circuit of FIG. 6B. The pin-out shows the bottom side of the IC that includes a multitude of metal electrodes and an insulating substrate. The IC can include a center ground serves as major path for dissipating heat generated by the active substrate. To keep the amplifiers running without excessive temperature, it is important to minimize the heat transfer resistance of the active substrate to external space on printed circuit. It is also desirable to have minimal electrical resistance for the current flowing between the center ground to the ground of the circuit board of the wireless device.

In the typical application for a wireless communication device, the IC of FIG. 7 is electrically mounted to a printed circuit board in the wireless communication device. The circuit board includes a grounding circuit design at the location where the IC is mounted.

Those skilled in the art will appreciate that semiconductor devices according to the present invention may include an integrated circuit die for wireless applications. An electronic system includes an input device and an output device coupled to a processor device which, in turn, can be coupled to an RF circuit incorporating the exemplary integrated circuit module 510 of FIG. 5.

The module 510 can also be employed to integrate digital or mixed signal circuits, for example, a microprocessor process die, a special graphics processor die, a memory die, a power management die, a medium access control (MAC) die, a base band (BB) die, a radio transceiver die, and that the present invention includes such devices within its scope. In addition, it will be understood that the shape, size, and configuration of bond pads, jumper pads, dice, and lead frames may be varied without departing from the scope of the invention and appended claims. For example, the jumper pads may be round, oblong, hemispherical or variously shaped and sized so long as the jumper pads provide enough surface area to accept attachment of one or more wire bonds thereto. In addition, the bond pads may be positioned at any location on the active surface of the die.

FIG. 8 shows a cross-sectional view of another embodiment of an RF module 800. The module 800 encapsulates circuit elements in a molding 802 such as a plastic molding. Pins 820 are provided to provide electrical I/Os for the module. The pins 820 are connected to active or passive substrates 806-808 using chip to pin wire-bonds 818. The substrates 806-808 are bonded to a die pad 804 using die bond 810, which can be a suitable epoxy or can be solder, among others. Additionally, connections inside a chip can be wire-bonded using intra-chip wire-bond 812. Moreover, connections between chips can be wire-bonded using inter-chip wire-bonds 814. In one embodiment, the pins can be gold plated (Au Plating). A ground base of nickel plating is provided to attach one or more dies thereto. Wires are bonded between the dies and the gold-plated pins. The entire assembly is then encapsulated in a mold to protect the power amplifier from environmental variables such as humidity and temperature and physical stress, among others.

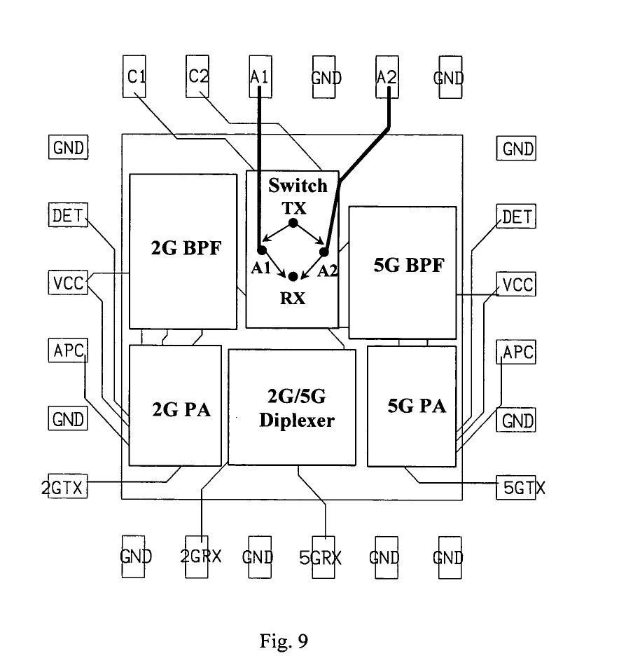

FIG. 9 shows the top view of an RF module with a plurality of active substrates and a plurality of passive substrates. In FIG. 9, a switch TX is centrally located. On one side of the switch TX are a passive substrate 2G BPF for 2 GHz band-pass filter and an active substrate 2G PA for 2 GHz power amplifier. On the other side of the switch are a passive substrate 5G BPF for 5 GHz band-pass filter and an active substrate 5G PA for 5 GHz power amplifier. A combined passive module 2G/5G Diplexer that performs filtering for both 2 GHz and 5 GHz is centrally positioned below the switch. The switch is a double pole double throw (DPDT) RF switch, which can be made with PHEMT.

In FIG. 9, A1 and A2 are antenna port 1 and antenna port 2, RX and TX are receiver port and transmitter port; C1 and C2 are logical signals which control how A1 & A2 are connected to TX & RX. For example, one of the logical states is TX being connected to A1. Another state is TX being connected A2. Another state is A1 being connected to RX. Yet another state is A2 being connected to RX.

In FIG. 9, DET is a power sensor output; VCC is the power supply input; APC is a signal to turn the power amplifier PA ON and OFF; 2GTX and 5GTX are the input RF inputs to the 2 GHz PA and 5 GHz PA, respectively; and 2GRX and 5GRX are the output RF signals for the 2 GHz and the 5 GHz receivers, respectively. The 2G BPF and 5G BPF, while physically separated by the switch, are electrically coupled to form a diplexer function for transmitting 2 GHz and 5 GHz signals.

The arrangement of FIG. 9 advantageously routes receiving signals from antenna ports A1 and A2 to receiver ports 2GRX and 5GRX. The arrangement of FIG. 9 also advantageously routes transmitting signal form transmitter ports 2GTX and 5GTX to antenna ports A1 and A2.

Although the foregoing description describes an exemplary embodiment working with a low frequency of 2 GHz and a high frequency of 5 GHz, other frequencies can be used as well. For example, Wi-Fi transceivers operate at approximately 2.4 GHz or 5 GHz bands (4.9 GH-5.85 GHz is generally referred as 5 GHz band). Similarly, Wi-Max transceivers operate at approximately 2.4 GHz, 3.5 GHz (3.3 GHz-3.7GHz), or 5 GHz. Moreover, cellular phones operate in specific frequencies that are country dependent, generally ranging from 450 MHz to 2200 MHz.

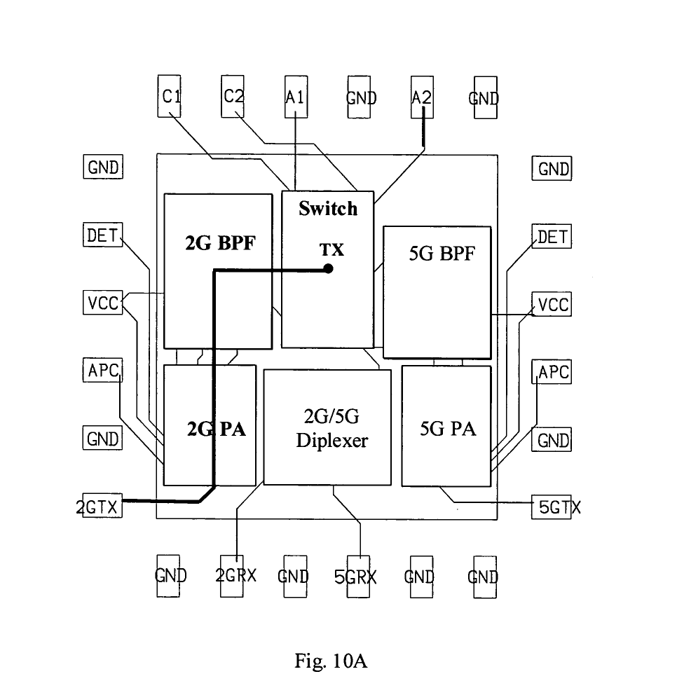

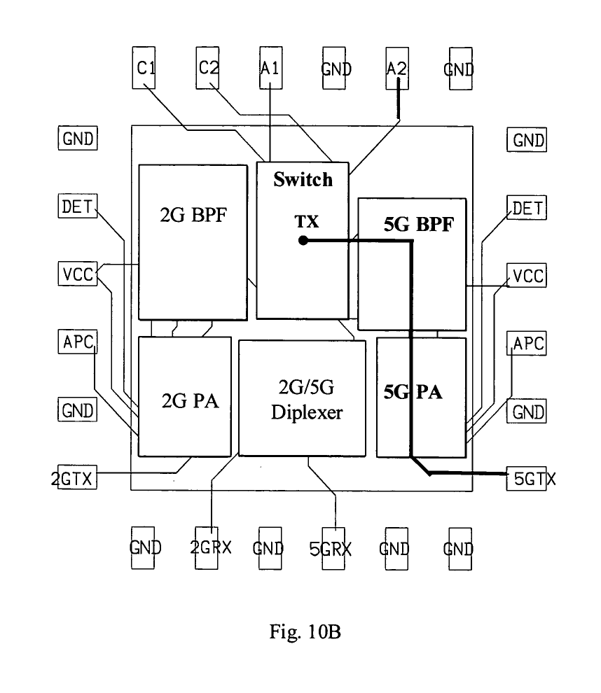

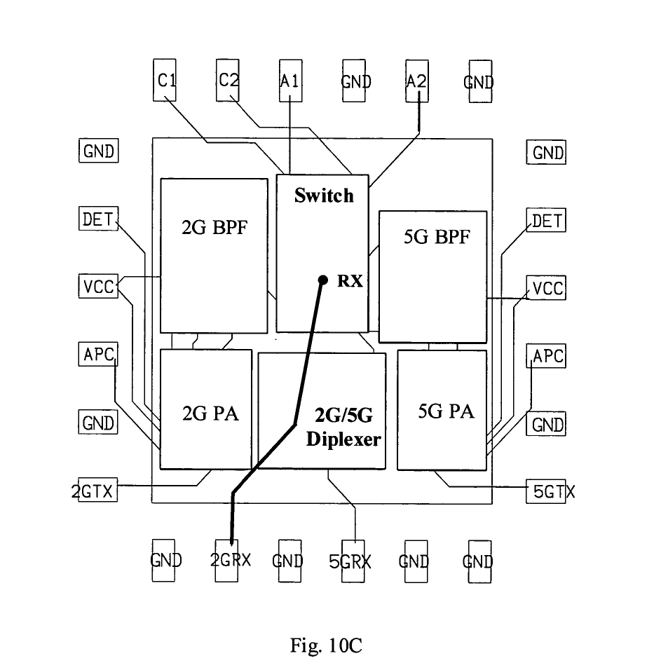

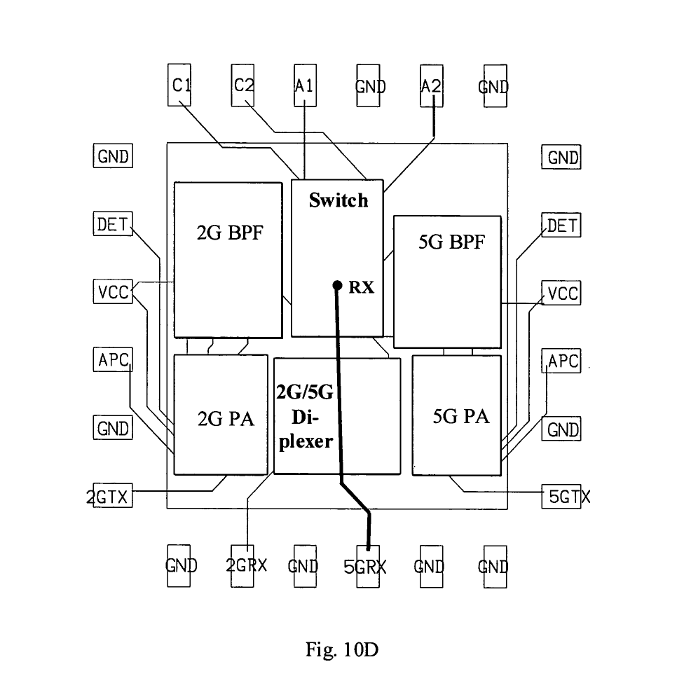

FIGS. 10A-10D illustrate various exemplary connections between the switch TX and RF input/output connections. FIG. 10A is used in a configuration when a 2 GHz RF signal is being transmitted. The RF signal path is as follows:

2GTX→amplified by 2GPA→2G BPF→TX

The transmitter output TX is connected either to antenna A1 or antenna A2 by control signals C1 and C2.

FIG. 10B illustrates a signal path for a 5 GHz RF signal transmission configuration. The RF signal path is as follows:

5GTX→amplified by 5G PA→5G BPF→TX

As discussed above, TX is further connected either to A1 or A2 by control signals C1 and C2.

FIG. 10C illustrates an exemplary configuration for receiving 2 GHz RF signals. The RF signal path is as follows:

Receive input RX is connected either to A1 or A2 by control signals C1 and C2.

RX→2G/5G Diplexer→2GRX

The 2 GHz signal is then provided to a receiver for processing. Optionally, a 2 GHz LNA can be used after the 2G/5G Diplexer.

FIG. 10D illustrates an exemplary configuration for receiving 5 GHz RF signals. The RF signal path is as follows:

Receive input RX is connected either to A1 or A2 by control signals C1 and C2.

RX→2G/5G Diplexer→5GRX

The 5 GHz signal is then provided to a receiver for processing. Optionally, a 5 GHz LNA can be used after the 2G/5G Diplexer.

The arrangement of FIGS. 10A-10D provides a clean routing of transmit and receive signals for the 2 GHz transceiver as well as the 5 GHz transceiver. Moreover, antenna connections for both frequencies are conveniently located for PCB routing and for minimizing spurious transmission or signal propagation.

Although specific embodiments of the present invention have been illustrated in the accompanying drawings and described in the foregoing detailed description, it will be understood that the invention is not limited to the particular embodiments described herein, but is capable of numerous rearrangements, modifications, and substitutions without departing from the scope of the invention. The following claims are intended to encompass all such modifications.

What is claimed is:

1. A device, comprising:
an active substrate comprising substantially transistors or diodes formed thereon, the active substrate having at least a radio frequency amplifier or a switch formed thereon;
a passive substrate comprising substantially inductors, capacitors or resistors formed thereon;
a plurality of bonding pads positioned on the active and passive substrates; and
bonding wires connected to the bonding pads.

2. The device of claim 1, wherein one of the substrate comprises gallium arsenide circuits.

3. The device of claim 1, wherein the active substrate comprises supporting passive components.

4. The device of claim 1, comprising one or more substantially passive integrated circuits for passive components only,

5. The device of claim 1, wherein the substrates are interconnected with bonding wires.

6. The device of claim 1, wherein the active substrate comprises primarily transistors.

7. The device of claim 1, wherein the transistors include silicon bipolar, CMOS, RFCMOS, BICOMS, SiGe, GaAs HBT, HEMT, or PHEMT.

8. The device of claim 1, wherein the transistors are fabricated on a wafer with semiconductor layer structure, junctions, and dopings.

9. The device of claim 1, wherein the passive substrate comprises a network of resistor (R), inductor (L), and capacitor (C) without active device structure.

10. The device of claim 1, wherein the passive substrate comprises one or more conductive metal layers for inductor (L) and interconnection.

11. The device of claim 1, wherein the passive substrate comprises an insulating layer with suitable dielectric properties.

12. The device of claim 11, wherein the insulating layer comprises one of nitride and oxide as a dielectric layer for a capacitor (C).

13. The device of claim 1, wherein the passive substrate comprises a layer including TaN or NiCr for a resistor (R).

14. The device of claim 1, wherein the passive substrate comprises one or more circuits of passive components including one of transmission lines, impedance matching network, filters, balun, and diplexers.

15. The device of claim 1, comprising an electronic circuit having an electrically conductive base and a three dimensional substrate having a conductive layer adapted to bond with the electrically conductive base.

16. The device of claim 1, wherein the amplifier comprises one of: a single-ended input and a double-ended input.

17. The device of claim 1, wherein the power amplifier is a single-ended input power amplifier, further comprising a balun coupled to the power amplifier to convert the single-ended input to a double-ended input.

18. The device of claim 1, wherein the balun is coupled to either the input or the output of the power amplifier.

19. The device of claim 1, wherein the balun is formed on the passive substrate.

20. The device of claim 1, comprising a plurality of active substrates and a plurality of passive substrates electrically coupled to one or more of the substrates.

21. The device of claim 1, wherein the active and passive substrates includes one or more metal patterns forming one of the following: transmission lines, microstrips, coplanar strips, coplanar waveguides and slot lines.

22. The device of claim 1, further comprising a switch centrally positioned in the device.

23. The device of claim 22, comprising
a. a passive substrate for a lower-frequency band-pass filter and an active substrate for a low frequency power amplifier on a first side of the switch;
b. a passive substrate for a higher-frequency band-pass filter and an active substrate for a high frequency power amplifier on a second side of a switch;
c. a diplexer positioned below the switch and coupled to the passive substrates for the low-frequency band-pass filter and the high-frequency band-pass filter.

24. The device of claim 23, wherein the low-frequency is in the 2 GHz band and the high-frequency is in the 5 GHz band.

25. The device of claim 24, comprising first and second antenna pins adapted to receive or transmit a low-frequency and a high-frequency RF signals respectively.

26. The device of claim 25, further comprising first and second receiver ports, wherein signals are routed from the first and second antenna pins to the first and second receiver ports, respectively.

27. The device of claim 26, further comprising first and second transmitter ports, wherein signals are routed from the first and second transmitter ports to the first and second antenna pins, respectively.

28. The device of claim 1, further comprising a lead-frame to receive the active and passive substrates, wherein the lead-frame comprises one or more fingers and wherein one or more of the bonding wires connect one or more bonding pads to the one or more fingers.
